(19) United States
(12) Patent Application Publication
(10) Pub. No.: US 2015/0233970 A1
(43) Pub. Date: Aug. 20, 2015

(54) CURRENT-SENSING CIRCUIT

(71) Applicant: GE Aviation Systems Limited, Gloucester (GB)

(72) Inventor: Peter James Handy, Cheltenham (GB)

(21) Appl. No.: 14/613,883

(22) Filed: Feb. 4, 2015

(30) Foreign Application Priority Data
Feb. 18, 2014 (GB) 1402824.5

(51) Int. Cl. G01R 1/20; G01R 19/00

(52) U.S. Cl. CPC G01R 1/203; G01R 19/0092

(57) ABSTRACT

A current-sensing circuit for determining an output current of an electrical component, the current-sensing circuit including a current-conducting electrical component having an first conductive segment, at least one bond wire electrically coupling the first conductive segment to a second conductive segment, and having a predetermined resistance profile, and a controller electrically coupled with the first conductive segment and the second conductive segment, and configured to determine the output current of the electrical component based on at least the resistance profile.

### BACKGROUND OF THE INVENTION

Electric components are modules positioned in electrical circuits to provide for designed circuit operations or characteristics. One example of an electrical component may include a diode, or a transistor. A transistor is a semiconductor device used to amplify and switch electronic signals and electrical power. It includes semiconductor material with at least three terminals for connection to an external circuit. A voltage or current applied to one pair of the transistor's terminals changes the current through another pair of terminals. Because the controlled output power can be higher than the controlling input power, a transistor can amplify a signal. Transistors may be packaged individually, but may also be embedded in integrated circuits.

The field-effect transistor (FET) is a type of transistor that uses an electric field to control the shape and hence the conductivity of a channel of one type of charge carrier in a semiconductor material. The FET controls the flow of electrons (or electron holes) from the source to drain by affecting the size and shape of a “conductive channel” created and influenced by voltage (or lack of voltage) applied across the gate and source terminals. This conductive channel is the “stream” through which electrons flow from source to drain.

### BRIEF DESCRIPTION OF THE INVENTION

In one embodiment, a current-sensing circuit for determining an output current of an electrical component, the current sensing circuit includes a current-conducting electrical component having an first conductive segment, at least one bond wire electrically coupling the first conductive segment to a second conductive segment, and having a predetermined resistance profile, and a controller electrically coupled with the first conductive segment and second conductive segment and configured to determine the output current of the electrical component based on at least the resistance profile.

In another embodiment, the invention relates to a current-sensing circuit in a solid state power controller for determining the output current of a transistor. The current sensing circuit includes a field-effect transistor (FET) having a source terminal, a gate terminal, and a drain terminal, an output lead, at least one bond wire electrically coupling the source terminal with the output lead and having a predetermined resistance profile, and a controller electrically coupled with the drain terminal and the output lead and configured to determine the output current of the FET based on at least the resistance profile of the at least one bond wire.

### BRIEF DESCRIPTION OF THE DRAWINGS

In the drawings:

FIG. 1 is a schematic view of a current-sensing circuit in accordance with a first embodiment of the invention.

FIG. 2 is a schematic view of a field-effect transistor, in accordance with a second embodiment of the invention.

FIG. 3 is a schematic view of the current-sensing circuit in accordance with a second embodiment of the invention.

### DESCRIPTION OF EMBODIMENTS OF THE INVENTION

While the embodiments of the invention may be implemented in any environment using an electronics circuit having an electrical component. Thus, a brief summary of the contemplated environment should aid in a more complete understanding.

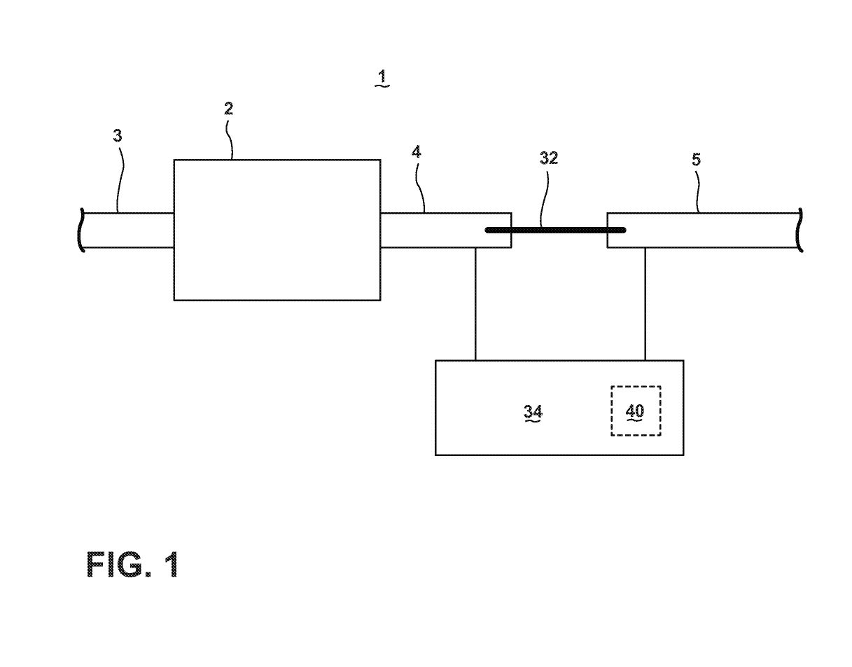

FIG. 1 schematically illustrates a first embodiment of a current-sensing circuit 1 having an electrical component 2, for example a diode, and a current path 3 having at least one conductive bond wire 32 electrically coupling a first and second conductive segments 4, 5 of the current path 3. The current-sensing circuit 1 further comprises a controller 34 electrically coupled with each of the two segments 4, 5.

It is also envisioned that the controller 34 is electrically coupled to each of the first and second segments 4, 5 such that the coupling may provide the controller 34 with a sensing or measuring of each respective segment 4, 5 voltage. While the controller 34 couplings are described as “sensing” and/or “measuring” the respective voltages, it is envisioned that sensing and/or measuring may include the determination of respective values indicative or related to the respective voltage characteristics, and not the actual voltage values.

Also as shown, the controller 34 may further comprise a resistance profile 40 for each respective bond wire 32, which may be variable or predetermined In one example, the controller 34 may store the resistance profile or profiles 40 in memory, such as random access memory (RAM), read-only memory (ROM), flash memory, or one or more different types of portable electronic memory, such as discs, DVDs, CD-ROMs, etc., or any suitable combination of these types of memory. In another example, the controller 34 may be operably coupled with remotely-accessible memory.

The resistance profile 40 for each respective bond wire 32 may be, for example, calibrated or estimated, based on one or more of: wire 32 material composition, circuit 1 structure, circuit packaging, manufacturing techniques, wire 32 diameter, wire 32 length, wire 32 heat capacity, expected operating temperature of one or more component (for example the diode 2, wire 32, or packaging), and/or wire 32 temperature. In one example, aluminum bond wires 32, which may be used in power applications, may have a resistance variation of 71% over a temperature range of −40 to +125° C. In this example, a fast current pulse at 30 amps, for less than one millisecond, through a bond wire may be known to raise the temperature by <1° C. It is envisioned that the resistance profiles 40 for multiple bond wires 32 may be similar or dissimilar. Furthermore, the nominal resistance profile 40 of the bond wires 32 can be designed by engineering aspects of the bond wires 32 themselves, such as the number of wires 32 (for example, to divide any current through said wires 32), wire 32, length, wire 32 diameter, etc.

The current-sensing circuit 28 operates to determine the output current of the diode 2, delivered by the conductive current path 3, based on at least a first sensed voltage at the first segment 4 and a second sensed voltage at the second segment 5. The controller 34, receiving each respective voltage, for example, calculates the voltage difference between the first and second segment, and using the resistance profile 40 of the bond wire 32, may calculate the current traversing the bond wire 32. In embodiments of the invention having a plurality of bond wires 32, it is envisioned that the controller 34 may additionally be capable of calculating the current traversing each individual bond wire 32.

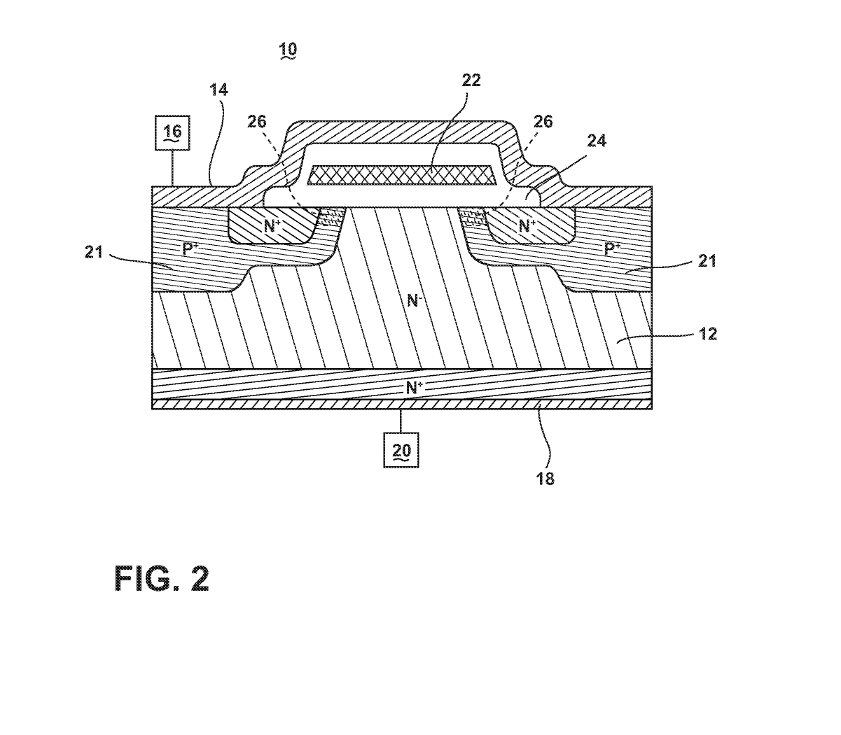

In another embodiment, the invention may be implemented in any environment using a semiconductor or transistor device and bond wires, such as in a solid state power controller (SSPC) module environment, having at least one transistor, such as a field-effect transistor (FET), such as in a power distribution system of an aircraft. Thus, a brief summary of the contemplated environment illustrating a layered transistor should aid in a more complete understanding. FIG. 2 schematically illustrates a vertical FET 10, and may typically comprise of a semiconducting material, for example a silicon body 12, having conductive drain terminal 14 electrically coupled with a power source 16 capable of providing current, a conductive source terminal 18 electrically coupled with a current destination, for example an electrical load 20 for receiving current, and an insulating region 21. The drain terminal 14 and source terminal 18 are separated by at least a portion the insulating region 21 having an adjacent conductive gate terminal 22, wherein the body 12 and gate terminal 22 are separated by a non-conductive and non-magnetic material, such as an oxide layer 24. As shown, the gate terminal 22 and oxide layer 24 span at least the portion of the insulating region 21 separating the source terminal 14 from the body 12.

When a sufficient voltage is applied to the gate terminal 22, the gate terminal 22 generates a magnetic field in the insulating region 21 such that conductive particles in the region 21 are drawn near the interface of the region 21 and oxide layer 24, creating a conductive channel 26, and allowing current to flow from the drain terminal 14 to the source terminal 18, via the body 12. In this sense, the FET 10 is a current-controlling component based on the application of a sufficient voltage to the gate terminal 22. One non-limiting example of a sufficient voltage may be any voltage at or greater than 5 VDC, however alternative sufficient voltages are envisioned, and may at least partially depend on the construction and materials of the FET 10.

While the description and operation of the above-described FET 10 is provided for understanding, embodiments of the invention are equally applicable to any transistor device, for example an insulated-gate bipolar transistor (IGBT) or bipolar junction transistor (BJT), and thus, the FET 10 is merely one non-limiting example as such. The above-described FET 10 is sometimes referred to as a metal-oxide-semiconductor field-effect transistor (MOSFET).

In an aircraft power distribution system, a SSPC module may comprise one or more FETs 10, controllable via the gate terminal 22 to switch output current on and off, as necessary. One example of the SSPC module may comprise a silicon carbide (SiC) or Gallium Nitride (GaN) based, high bandwidth power switch. SiC or GaN may be selected based on their solid state material construction, their ability to handle large power levels in smaller and lighter form factors, and their high speed switching ability to perform electrical operations very quickly. For example, one SSPC may be able to handle 6 Amps (100% rated) continuous current, and 30 Amps (500% rated) current for 100 microseconds during an over-current event. Another example of the SSPC module may further comprise a silicon-based power switch, similar to the embodiment shown above, also capable of high speed switching. The SSPC module may also provide power conversion capabilities for the power distribution system, for example, converting input power at 28 VDC to a 270 VDC output. Alternative examples of SSPC modules and/or power conversion are envisioned.

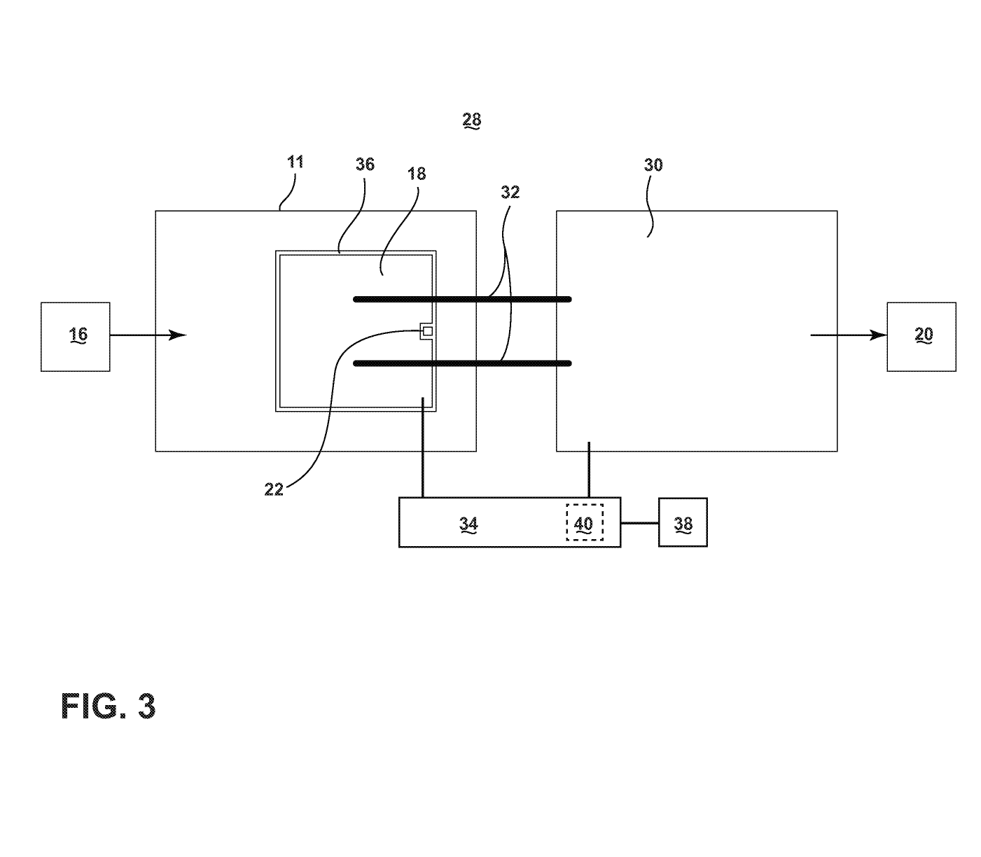

FIG. 3 illustrates a schematic view of a current-sensing circuit 28, in accordance with a second embodiment of the invention. The second embodiment is similar to the first embodiment; therefore, like parts will be identified with like numerals, with it being understood that the description of the like parts of the first embodiment applies to the second embodiment, unless otherwise noted. As shown, the current-sensing circuit 28 comprises a conductive plate, such as a copper plate 11 having the source terminal 18, the gate terminal 22, an output lead 30, and at least one conductive bond wire 32, shown having two bond wires, electrically coupling the source terminal 18 with the output lead 30, and a controller 34 electrically coupled to each of the source terminal 18 and output lead 30.

The current-sensing circuit 28 may also optionally include a temperature sensor 38 transmissively coupled with the controller 34, and capable of providing a sensing or measuring of a temperature, to the controller 34. While the temperature sensor 38 is described as “sensing” and/or “measuring” the temperature, it is envisioned that sensing and/or measuring may include the determination of a value indicative or related to the temperature characteristics, and not the actual temperature values. It is envisioned the temperature sensor 38 is capable of sensing or measuring the temperature of at least one of the following components: the FET 10, the current-sensing circuit 28, and/or the bond wires 32.

The FET 10 is shown further comprising a MOSFET die 36, which may incorporate the silicon body 12, insulating region 21, oxide layer 24, and conductive channel 26, or like components, and operatively provide for FET 10 operation, as described above, when a sufficient voltage is applied to the gate terminal 22. Furthermore, it is envisioned the drain terminal of the FET 10 is electrically coupled with the copper plate 11.

It is also envisioned that the controller 34 is electrically coupled to each of source terminal 18 and the output lead 30 such that the coupling may provide the controller 34 with a sensing or measuring of each respective source terminal 18 voltage and output lead 30 voltage. While the controller 34 couplings are described as “sensing” and/or “measuring” the respective voltages, it is envisioned that sensing and/or measuring may include the determination of respective values indicative or related to the respective voltage characteristics, and not the actual voltage values.

The resistance profile 40 for each respective bond wire 32 may be, for example, calibrated or estimated, based on one or more of: wire 32 material composition, FET 10 structure, circuit packaging, manufacturing techniques, wire 32 diameter, wire 32 length, wire 32 heat capacity, expected operating temperature of one or more component (for example the FET 10, wire 32, or packaging), and/or wire 32 temperature.

In an embodiment of the invention, wherein the optional temperature sensor 38 is not provided, the resistance profile 40 may further comprise a predetermined or estimated temperature profile, and may operably provide a temperature sensing or measuring to the controller 34. For example, the temperature profile may take into account an expected self-heating of bond wires 32, based on the amount of current through the wires 32. Additional factors or characteristics included in the current-sensing circuit that may affect either the resistance profile 40 or temperature profile are envisioned. It is envisioned the temperature profile may be calibrated to reduce or eliminate a change in resistance introduced by, for example, the resistance temperature coefficient of the bond wire 32 material.

In another example, the controller 34 may utilize the temperature provide by the temperature sensor 38, temperature profile, or may calculate estimation of temperature of one or more components of the current-sensing circuit 28, and use this temperature in calculating the current through the bond wires 32 collectively, or individually, as explained above. Alternatively, it is envisioned that the resistance profile 40 may take into account any of the previously described sensed or measure temperatures, and may adjust the profile 40 accordingly in calculating the current traversing the bond wires 32.

Furthermore, embodiments of the invention may be implemented in modules comprising a plurality of FETs 10, wherein each FET 10 has a respective output lead 30, at least one bond wire 32 electrically coupling the respective drain terminals 18 with the respective output lead 30, and each respective source terminal 18 and respective output lead 30 is electrically coupled to the controller 34. In this sense, the controller 34 may be capable of calculating, estimating, or otherwise providing a current calculation for each FET 10, or for a collective group of FETs 10 per module. In this embodiment, it is envisioned one or more optional temperature sensor 38 may provide a sensed temperature for each individual FET 10, for each module, or for a grouping there between. Similarly, a single controller 34 may be capable of providing a current measurement for a plurality of modules.

Many other possible embodiments and configurations in addition to that shown in the above figures are contemplated by the present disclosure. For example, the first embodiment may provide a temperature sensor 38 as in the second embodiment, and calculate the current utilizing a temperature profile. Additionally, the design and placement of the various components may be rearranged such that a number of different in-line configurations could be realized.

The embodiments disclosed herein provide a current-sensing circuit for determining the output current of a current-conducting electrical component. A technical effect of the embodiments is a method for determining the output current of a current-conducting electrical component. One advantage that may be realized in the above-embodiments is that the above-described embodiments eliminate the need to configure an additional current sensor in-line with a current-conducting electrical component or transistor. In many instances, the sizing of the current sensor is significantly larger than the current-conducting electrical component or transistor itself, and requires significant printed circuit board or substrate area. Thus the above-described embodiments have superior weight and size advantages over the conventional type current measurement configurations for current-conducting electrical component or transistor systems. Additionally, by removing the conventional sense resistors, the significant cost savings can be achieved when producing circuitry having many FETs. Additionally, the above-described embodiments provide for determining the current output of each FET using a resistance profile and/or temperature profile without requiring a temperature sensor, and thus, may provide accurate current measurements while further reducing costs associated with including a temperature sensor.

Moreover, in power system embodiments, obtaining a current measurement for a FET allows for controlling the FET, a module of FETs, or a subgroup of FETs to share a load current evenly between the respective FETs, for example, by employing a closed loop control and op-amp at each FET output.

To the extent not already described, the different features and structures of the various embodiments may be used in combination with each other as desired. That one feature may not be illustrated in all of the embodiments is not meant to be construed that it may not be, but is done for brevity of description. Thus, the various features of the different embodiments may be mixed and matched as desired to form new embodiments, whether or not the new embodiments are expressly described. All combinations or permutations of features described herein are covered by this disclosure.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

What is claimed is:

1. A current-sensing circuit for determining an output current of an electrical component, the current-sensing circuit comprising:
a current-conducting electrical component having an first conductive segment;
at least one bond wire electrically coupling the first conductive segment to a second conductive segment, and having a predetermined resistance profile; and
a controller electrically coupled with the first conductive segment and second conductive segment and configured to determine the output current of the electrical component based on at least the resistance profile.

2. The current-sensing circuit of claim 1, wherein the controller is configured to determine the output current of the electrical component based on a first sensed voltage at the first conductive segment and a second sensed voltage at the second conductive segment.

3. The current-sensing circuit of claim 1, wherein the controller is configured to determine the output current of the electrical component based on a first sensed voltage at the first conductive segment, a second sensed voltage at the second conductive segment, and the predetermined resistance profile.

4. The current-sensing circuit of claim 1, further comprising a sensed temperature operably provided to the controller and indicative of the temperature of at least one of the electrical component or current-sensing circuit.

5. The current-sensing circuit of claim 4, wherein the controller is configured to determine the output current of the electrical component based a first sensed voltage at the first conductive segment, a second sensed voltage at the second conductive segment, the predetermined resistance profile, and the sensed temperature.

6. The current-sensing circuit of claim 1, wherein the electrical component comprises a transistor as a component in a solid state power controller, the transistor comprising:
a source terminal;
a gate terminal; and
a drain terminal;
wherein the at least one bond wire electrically couples the source terminal with the second conductive segment and the controller electrically couples with the source terminal and the second conductive segment.

7. A current-sensing circuit in a solid state power controller for determining an output current of a transistor, the current sensing circuit comprising:
a field-effect transistor (FET) comprising:
a source terminal;
a gate terminal; and
a drain terminal;
an output lead;
at least one bond wire electrically coupling the source terminal with the output lead and having a predetermined resistance profile; and
a controller electrically coupled with the source terminal and the output lead and configured to determine the output current of the FET based on at least the resistance profile of the at least one bond wire.

8. The current-sensing circuit of claim 7, wherein the controller is configured to determine the output current of the FET based on a first sensed voltage at the source terminal and a second sensed voltage at the output lead.

9. The current-sensing circuit of claim 7, wherein the controller is configured to determine the output current of the FET based on a first sensed voltage at the source terminal, a second sensed voltage at the output lead, and the predetermined resistance profile.

10. The current-sensing circuit of claim 7, further comprising a sensed temperature operably provided to the controller and indicative of the temperature of at least one of the FET or current-sensing circuit.

11. The current-sensing circuit of claim 10, wherein the resistance profile further comprises a predetermined temperature profile operably providing the sensed temperature.

12. The current-sensing circuit of claim 10, wherein the controller is configured to determine the output current of the FET based a first sensed voltage at the source terminal, a second sensed voltage at the output lead, the predetermined resistance profile, and the sensed temperature.

13. The current-sensing circuit of claim 10, further comprising a module comprising a plurality of FETs, each FET having an output lead, at least one bond wire electrically coupling the respective source terminal with the respective output lead, and each respective drain terminal and respective output lead electrically coupled with the controller.

14. The current-sensing circuit of claim 13, wherein the sensed temperature is provided for each FET.

15. The current-sensing of claim 1, wherein the sensed temperature is provided for each current-sensing circuit.
